(19) United States
(12) Patent Application Publication
(10) Pub. No.: US 2010/0221495 A1
(43) Pub. Date: Sep. 2, 2010

(54) Method of Manufacturing a Transparent Member and Plastic Member

(75) Inventors: Tadahiro Ohmi, Miyagi (JP); Naoki Tanahashi, Miyagi (JP); Keiichi Nii, Miyaki (JP)

Correspondence Address: FOLEY AND LARDNER LLP;SUITE 500, 3000 K STREET NW, WASHINGTON, DC, 20007, US

(73) Assignee: Tadahiro OHMI

(21) Appl. No.: 11/991,795

(22) PCT Filed: Sep. 12, 2005
(86) PCT No.: PCT/JP2005/016716

§ 371 Date: Mar. 11, 2008

(51) Int. Cl. B32B 3/30; C23C 16/44; B32B 27/00; B32B 27/32; B32B 3/28

(52) U.S. Cl. 428/172; 427/255.4; 428/411.1; 428/500; 428/174

(57) ABSTRACT

A plastic member, for example, a hydrocarbon-based transparent polymer molded product is subjected to fluorination processing in a fluorine gas within a reaction device 8 to fluorinate only a surface layer thereof. Thus, a refractive index can be lowered, a surface reflection can be lowered, and light transmittance of a base material can be improved.

### TECHNICAL FIELD

This invention relates to a plastic member and a transparent member and, in particular, to a plastic member and a transparent member each of which has a fluorinated surface, and to a method of manufacturing the plastic member and the transparent member.

### BACKGROUND ART

With the developments in optical and laser technologies, a transparent resin material has become used in an optical member, such as an optical lens, a prism, and a light guiding member, for which a transparent material, such as glass, has heretofore been used.

The optical member made of resin is advantageous in that it is lightweight in comparison with glass and that an optical member having a complicated shape, such as an aspheric or a microscopic shape, can easily be mass-produced, which has been difficult to be produced by glass.

Therefore, it becomes possible to achieve reduction in weight and in size of an optical apparatus using the optical member made of resin.

For example, a conventional lens mounted to an advanced camera uses a plurality of spherical glasses laminated on one another. Therefore, a telephoto lens is increased in size and in weight and hard to handle.

However, use of the aspheric resin lens makes it possible to substantially reduce the number of lenses to be used. Accordingly, the telephoto lens is reduced in weight and in size and can easily be handled by everyone.

Also in a flat-panel liquid crystal display which is recently increased in demand, a resin optical sheet or plate is used which has a complicated shape.

Without such optical member made of transparent resin, reduction is impossible in thickness and in weight of the flat-panel display.

In particular, a large-size flat-panel liquid crystal display is drastically increased in demand in recent years which has a diagonal screen size of 28 inches or more, and which is advantageous in that it is overwhelmingly thinner and lighter than a cathode-ray tube (CRT) which is a mainstream display at present. This is a revolutionary display which is easy to carry and can be hung on the wall to achieve space-saving in a room.

The reduction in thickness and in weight is also achieved by presence of the optical member made of the transparent resin. Thus, examples of applications of the transparent resin to the optical member are spectacularly improved.

Incidentally, due to the developments of the optical member made of the transparent resin, requirements to the optical member become more and more severe. In recent years, it is required that an optical member has a higher light transmittance, in other words, a low surface reflection is required.

Each of the glass material and the transparent resin has been used in the past which has a specific refractive index.

The refractive index of the transparent resin is, for example, about 1.50 for acrylic resin called organic glass, about 1.60 for polycarbonate, and about 1.54 for cyclic olefin resin.

On the other hand, light incident to these resins or light emitted from these resins passes from or into the air. Incidentally, a refractive index of the air is 1.0.

From Fresnel equation, a surface reflectance R of a substance is given by the following Formula 1:

R=(n₁−n₂)²/(n₁+n₂)²×100(%) [Formula 1]

n₁, n₂: refractive indexes of the substance before and after an interface

According to the above-mentioned Formula 1, it is understood that, as the refractive index is smaller, a surface reflection is lower.

Heretofore, in order to lower the surface reflection, a material surface is generally provided with a low-refraction film.

In order to suppress the surface reflection, a film having a thickness corresponding to ¼ of a wavelength of light is typically provided in accordance with a phase condition equation given by the following Formula 2, so that a reflected light at an interface between the air and the low-refraction film and a reflected light at an interface between the low-refraction film and a base material interfere with each other to cancel each other.

d=(¼)λ/n [Formula 2]

d: the film thickness, λ: the wavelength, n: the refractive index of a substance forming the film

As the low-refraction film, an inorganic material, such as SiO₂ and MgF, which has a low refractive index is used.

These materials are generally deposited by a wet method, such as solvent casting or spin coating, or by a dry method, such as vapor deposition or sputtering.

However, these methods are disadvantageous in that the cost is high not only because one more step is additionally required but also because the film is deposited by the use of a different material, that the film is easily peeled off in case of poor adhesion with the base material, and so on.

On the other hand, as a method of making the transparent resin have a low refractive index, a method of fluorinating the resin is reported (for example, see Patent Document 1).

Patent Document 1 describes a method of controlling a refractive index of an optical polymer material by fluorination.

Patent Document 1 discloses that, for the purpose of increasing a fluorine content and lowering a refractive index, fluorinated polyimide is exposed in a fluorine gas.

However, with the method of Patent Document 1, since the material is already fluorinated, a difference in refractive index between a low-refractive layer to be formed and the base material is small and, since an interface between the fluorinated layer and the base material is not clear, a surface reflection effect due to interference can not be expected.

Further, Patent Document 2 describes a method of forming a fluoric resin film.

The method disclosed in Patent Document 2 is definitely intended to lower a dielectric constant of a material and is not a technique of forming the low-refractive layer as means for lowering a surface reflectance.

In a material fluorinated by the method disclosed in Patent Document 2, a light transmittance of the base material itself is lowered. Therefore, this method does not meet the essential object of improvement of transmittance by prevention of the surface reflection.

Patent Document 1: Japanese Unexamined Patent Application Publication (JP-A) No. 2000-95862

Patent Document 2: Japanese Unexamined Patent Application Publication (JP-A) No. H6-69190

### DISCLOSURE OF THE INVENTION

### Problem to be Solved by the Invention

The present invention has been made, focusing on the above-mentioned circumstances. It is an object of the present invention to provide a processing method and a member in which a conventional surface antireflection technique of depositing another low-refractive material to lower a surface reflection to thereby improve a light transmittance is more easily carried out.

It is another object of the present invention to provide a method of easily obtaining a plastic member having a fluorinated layer on a surface thereof.

### Means to Solve the Problem

According to one aspect of this invention, there is provided a method of manufacturing a transparent member, which includes a step of preparing a member having a transparent hydrocarbon polymer at least on a surface portion thereof and a step of exposing a surface of the transparent hydrocarbon polymer to an atmosphere containing a fluorine gas to thereby fluorinate at least a part of the transparent hydrocarbon polymer. It is preferable that the member is substantially transparent plastic, and that the step of preparing includes a step of forming a film of the transparent hydrocarbon polymer on a substantially transparent plastic substrate.

According to another aspect of this invention, there is provided a method of manufacturing a transparent member, which includes a step of forming a hydrocarbon material film on a substantially transparent plastic substrate and a step of bringing a surface of the hydrocarbon material film into contact with an atmosphere containing a fluorine gas to fluorinate at least a part of the hydrocarbon material film. It is preferable that the step of forming the film includes a step of bringing the surface of the substrate into contact with a liquid or a gaseous organic material to adhere the hydrocarbon material film onto the substrate, that the plastic substrate contains a transparent hydrocarbon polymer, and that the transparent hydrocarbon polymer is a cyclic olefin polymer. It is also preferable that the method further includes a step of forming a second hydrocarbon material film on the fluorinated hydrocarbon material film and a step of bringing a surface of the second hydrocarbon material film into contact with an atmosphere containing a fluorine gas to fluorinate at least a part of the second hydrocarbon material film, and that the transparent plastic substrate comprises a cyclic olefin polymer and the second hydrocarbon material film comprises straight-chain saturated or unsaturated hydrocarbon.

It is also preferable that the member or the plastic substrate has a first principal surface having a substantially planar or curved shape and a second principal surface having a substantially planar or curved shape and opposite to the first principal surface. At least one of the first and the second principal surfaces has the hydrocarbon polymer or, alternatively, the step of forming the film is carried out on at least one of the first and the second principal surfaces to form the film.

According to still another aspect of this invention, there is provided a method of manufacturing a transparent member, which includes a step of exposing a surface of at least a part of a transparent hydrocarbon polymer member to vaporized hydrocarbon or liquid hydrocarbon to form a hydrocarbon layer having a composition different from that of the polymer base material and a step of exposing the hydrocarbon layer to an atmosphere containing a fluorine gas to fluorinate the hydrocarbon layer. The method may further includes a step of forming a second hydrocarbon layer on the fluorinated hydrocarbon layer and a step of exposing a surface of the second hydrocarbon layer to an atmosphere containing a fluorine gas to fluorinate the second hydrocarbon layer. The transparent hydrocarbon polymer may be, for example, a cyclic olefin polymer, i.e. cycloolefin polymer. It is preferable that the vaporized hydrocarbon is vaporized from a hydrocarbon material which is solid at a temperature when the surface of the transparent hydrocarbon polymer member is exposed, and that the second hydrocarbon layer includes straight-chain saturated or unsaturated hydrocarbon.

It is preferable that the atmosphere containing a fluorine gas is a mixed gas atmosphere of the fluorine gas and an inert gas, and each of a moisture concentration and an oxygen concentration in the inert gas is 1 ppm or less.

According to yet another aspect of this invention, there is provided a transparent member having a transparent hydrocarbon polymer at least on a surface thereof, in which at least a part of a surface of the transparent hydrocarbon polymer is fluorinated. The transparent hydrocarbon polymer may be, for example, a cyclic olefin polymer. This invention also provides a transparent member manufactured by the above-mentioned method.

According to a further aspect of this invention, there is provided a plastic member which contains at least carbon atoms and hydrogen atoms. In the plastic member, at least a part of the hydrogen atoms on and adjacent to a surface of at least a part of the plastic member are substituted by fluorine atoms. It is preferable that a concentration of the fluorine atoms adjacent to the surface is reduced from the surface toward the inside. It is also preferable that the plastic member comprises on the surface, a fluorocarbon film which includes carbon atoms and fluorine atoms as main components and which has a fluorine atom concentration substantially constant in a thickness direction. As the optical plastic member, it is necessary that the plastic member is substantially transparent with respect to light. It is preferable that the plastic member has a first principal surface having a substantially planar or curved shape and a second principal surface having a substantially planar or curved shape and opposite to the first principal surface, in which at least a part of the hydrogen atoms on or adjacent to a surface of at least a part of at least one of the first principal surface and the second principal surface is substituted by fluorine atoms; that the plastic member has a flat plate shape; that at least one principal surface of the plastic member of a flat plate shape is provided with at least one of a convex structure, a concave structure, and a concavo-convex structure; that both principal surfaces of the plastic member has a flat plate shape are provided with at least one of a convex structure, a concave structure, and a concavo-convex structure; that the plastic member has a first principal surface having a substantially planar or curved shape and a second principal surface having a substantially planar or curved shape and opposite to the first principal surface, in which at least one of the first principal surface and the second principal surface has at least one or a plurality of, for example, an array of surface structures, which scatter, refract, or reflect light, for example, a lens structure, depending on intended use.

Since the above-mentioned plastic member has a fluorinated surface, its strength is improved. Therefore, the plastic member can be formed into a film to have a membrane structure and can be used for a degassing membrane, an ultrafilter membrane, or the like. Further, the above-mentioned plastic member may have a filter structure.

The plastic member and the transparent member can be used as various optical members, such as a lens, a prism, and an optical sheet, and can widely be used as one component of an optical device, a flat panel display device, and other electronic devices.

### EFFECT OF THE INVENTION

In the present invention, since hydrogen is easily substituted by fluorine, a plastic member containing carbon atoms and hydrogen atoms, i.e., a hydrocarbon plastic member, such as a cycloolefin polymer, has a surface which is easily fluorinated. Therefore, it is possible to easily obtain, at a low cost, a surface layer having a low refractive index and suppressed in surface reflection or a surface layer improved in strength.

According to the present invention, it is possible to easily form a low-refraction fluorinated layer on a surface of a transparent polymer without requiring a large-scale device so as to further improve a reflection suppression effect and a light transmittance enhancing effect.

### BRIEF DESCRIPTION OF THE DRAWING

FIG. 1 is a view of a fluorination processing device according to an embodiment of the present invention.

### DESCRIPTION OF REFERENCE NUMERALS

1 inert gas supply pipe
2 flow rate controller
3a, 3b, and 3c valve (double three-way valve)
4 hydrocarbon vaporization device
5 hydrocarbon
7 fluorine gas supply pipe
8 reaction device
9 material (polymer molded product)
10 exhaust pipe
11 reaction gas supply pipe
12 inert gas supply pipe
100 transparent hydrocarbon polymer processing device

### BEST MODE FOR EMBODYING THE INVENTION

Hereinbelow, an embodiment of the present invention will be described with reference to the drawing.

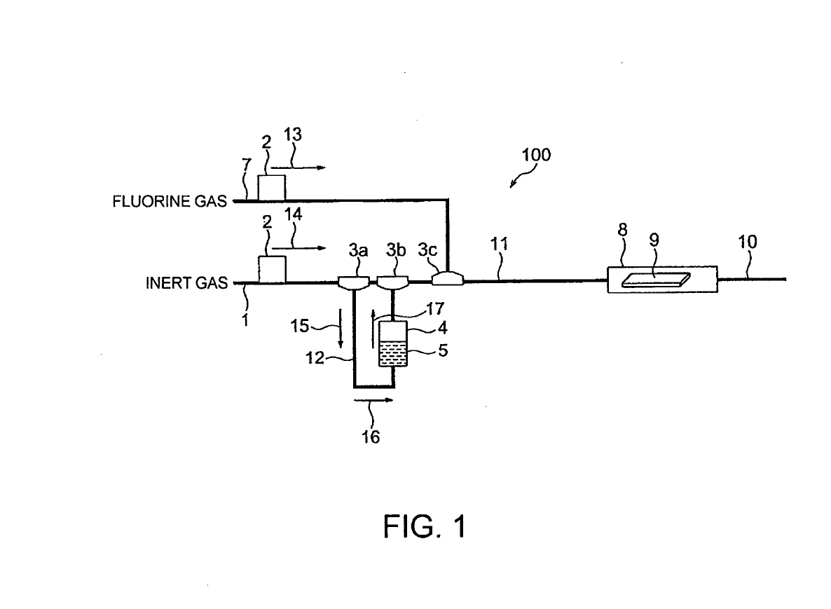

FIG. 1 is a view showing a schematic structure of a processing device for a transparent hydrocarbon polymer, according to the embodiment of the present invention. Referring to FIG. 1, the transparent hydrocarbon polymer processing device 100 has a hollow reaction device 8 in which an object material 9 to be processed is inserted therein. A fluorine gas is supplied through a fluorine gas supply pipe 7 which is provided with a flow rate controller 2. An inert gas is supplied through an inert gas supply pipe 1 which is provided with valves 3a and 3b for branching and combining. A branch pipe 12 branched by the valves 3a and 3b is provided with a hydrocarbon vaporization device 5 containing hydrocarbon 5. The inert gas supply pipe 1 and the fluorine gas supply pipe 7 are combined through a valve 3c and connected to a reaction gas supply pipe 11 which is connected to one end of the reaction device 8. The reaction device 9 has the other end which is provided with an exhaust pipe 10.

Herein, description will be made more in detail about the present invention.

The present invention provides a processing method in which the above-mentioned processing device and so on are used for fluorinating the transparent hydrocarbon polymer to form a fluorinated hydrocarbon layer having a refractive index smaller than that of the transparent hydrocarbon polymer as a base material. The surface-fluorinated transparent hydrocarbon polymer has a characteristic that a surface reflectance is small due to an effect of interference of light.

In order to obtain the fluorinated transparent hydrocarbon polymer, the transparent hydrocarbon polymer is fluorinated.

As a method of the fluorination, there are (a) a method of directly fluorinating the base material, (b) a method of forming a hydrocarbon layer having another composition on the base material and fluorinating the hydrocarbon layer, and (c) a method of forming another hydrocarbon layer on a fluorinated layer and carrying out fluorination again.

In each method, the fluorinated layer is adjusted to have a desired thickness to thereby achieve surface antireflection as intended.

The reason why fluorination processing is carried out after the hydrocarbon layer is formed in (b) mentioned above is to define an interface. By clarifying the interface between the fluorinated layer and the base material and uniformizing lights reflected on the interface, an interference effect with the reflected lights is rendered effective.

The reason why another fluorinated layer is formed again on the fluorinated layer in (c) mentioned above is to provide an antireflection function with respect to lights in a wide wavelength range by forming a plurality of fluorinated layers having various refractive indexes.

Incidentally, as the transparent hydrocarbon resin, there is a general-purpose polymer, such as polyethylene and polypropylene. The present invention is applicable also to these polymers. However, these general-purpose polymers are not often used as an optical material because they are inferior in transparency, heat resistance, and purity.

On the other hand, a cyclic olefin polymer is especially excellent in transparency, heat resistance, and purity so that even a monomer is satisfactorily applied as an optical material. Therefore, by using a processing technique of the present invention, the cyclic olefin polymer can be provided with higher antireflection function and further improved in transparency.

In the present invention, the transparent hydrocarbon polymer is dipped into a fluorine gas atmosphere to form a fluorinated layer. Thus, a refractive index of a polymer material can be lowered so as to lower a surface reflectance.

By suitably selecting a fluorine gas concentration in the fluorine gas atmosphere and a temperature and a time for dipping in the fluorine gas atmosphere, a thickness of the fluorinated layer and a fluorination rate of the polymer can arbitrarily be controlled and a surface reflectance for a desired wavelength can be lowered.

Herein, the fluorine gas atmosphere means a gas containing a fluorine gas and may be a mixed gas of the fluorine gas and an inert gas, such as nitrogen and argon.

The concentration of the fluorine gas in the fluorine gas atmosphere can be suitably selected depending on a desired refractive index and a desired thickness of the fluorinated layer of the material.

Further, the transparent hydrocarbon polymer used in the present invention is a polymer comprising carbon and hydrogen as constituent elements. In addition to the example mentioned above, any polymer comprising carbon and hydrogen may be used without specific limitation.

It is noted here that an additive, such as an antiaging agent, an ultraviolet absorber, and a plasticizer, which is added to these polymers and which has a content not greater than 5% with respect to the total weight, may comprise an element or elements other than carbon and hydrogen.

Further, even in case where a polymerization aid material, such as a catalyst and a reaction stopper, for use in manufacturing the polymer remains unremoved, constituent elements thereof are not limited to carbon and hydrogen as long as the residual amount is less than 1% with respect to the total weight.

In the present invention, the transparent hydrocarbon polymer is not specifically limited as long as the above-mentioned conditions are satisfied. However, taking into account high transparency, high heat resistance, low water absorption, high purity, and low birefringence, the cyclic olefin polymer is preferable.

By exposing the polymers in fluorine gases which are diluted by, for example, a nitrogen gas or the like and which have various concentrations at a predetermined temperature for a predetermined time, introduction of fluorine into molecules gradually occurs from a surface toward the inside of the polymer material. Thus, a fluorine content of the material increases.

A depth of penetration of fluorine from the surface of the material and the fluorine content in the material after fluorination processing are varied depending on the concentration of the fluorine gas, a fluorination processing temperature, and a fluorination processing time.

There is no specific limitation imposed upon these conditions. However, in case of a high fluorine concentration, in case of a long processing time, and in case of a high processing temperature, the depth of penetration of fluorine is increased and the fluorine content of the polymer material after fluorination processing is increased.

In association with the increase of the fluorine content, a refractive index of a fluorinated portion is lowered. Hence, it is possible to form a low-refraction fluorinated layer having a desired thickness if a fluorine concentration, a processing temperature, and a processing time are suitably selected.

However, in case where the fluorine concentration is extremely high or the fluorination processing is carried out at an extremely high temperature for an extremely long time, molecules are deteriorated. As normal conditions for the fluorination processing, it is preferable that the fluorine concentration is 1 ppm to 10%, the processing temperature is 0 to 100° C., and the processing time is 0.1 second to 60 minutes.

Herein, there is a processing method in which a hydrocarbon layer is formed before the fluorination processing is carried out.

The hydrocarbon layer is formed by exposing the polymer in a vaporized hydrocarbon gas atmosphere. The hydrocarbon gas atmosphere means only a hydrocarbon gas or a mixed gas of a hydrocarbon gas and an inert gas.

Generally, either gas is usable. However, for easy control of reactions and a uniform layer thickness, the mixed gas of the hydrocarbon gas and the inert gas is preferable. The mixing ratio is preferably 1 ppm to 50%.

Preferably, the processing temperature is 0° C. to 50° C. and the processing time is 0.1 second to 60 minutes. Hydrocarbon to be used may be straight-chain, cyclic, saturated, or unsaturated without specific limitation. However, in view of reaction activity and uniformity, straight-chain or cyclic saturated hydrocarbon is preferable.

Further, in view of handling after the processing, hydrocarbon is preferably solid at a temperature not higher than a normal temperature (30° C.). Hydrocarbon in a liquid phase is not preferable because the layer flows and the base material swells.

In the present invention, there is a processing method in which a hydrocarbon layer is formed after the fluorination processing and again fluorinated to obtain a multi-layer structure of the fluorinated layers.

A lens for visible light and an optical film generally function with respect to a group of lights having wavelengths between about 400 nm to 700 nm. Therefore, surface antireflection must be effected with respect to the wavelengths in such a wide band.

Therefore, by obtaining the multi-layered structure, it is possible to cover lights having wavelengths in a wider band.

According to the method of the present invention, it is possible to form a desired number of low-refraction fluorinated layers having a desired layer thickness and a desired refractive index.

Taking into consideration the economical aspect and the uniformity in layer thickness, the number of layers is, in general, preferably 1 to 20.

The fluorine gas or the mixed gas of the fluorine gas and the inert gas for use in the present invention is required to have a high purity so as to suppress an abnormal reaction also.

Particularly, the purity of the inert gas to be mixed with the fluorine gas is important. Especially, moisture contained in the inert gas reacts with the fluorine gas when the inert gas is mixed with the fluorine gas to produce hydrogen fluoride which inhibits a uniform reaction. Therefore, the moisture must be minimized.

Generally, the moisture contained in the inert gas is preferably 1 ppm or less, more preferably 100 ppb or less, further preferably 10 ppb or less.

Hereinbelow, specific examples of the present invention will be described. It is noted here that the following specific examples are no more than mere examples. It is readily understood that the present invention is not limited to the specific examples.

I. (Preparation of Samples)

By using a device as shown in FIG. 1, a polymer is exposed to a fluorine gas and a hydrocarbon gas.

### Example 1

In the device of FIG. 1, a cyclic olefin polymer molded plate having a thickness of 1 mm is inserted into a reaction container 6 kept at 25° C. and a high-purity argon gas containing moisture not more than 1 ppb is introduced therein to completely replace the inside of the reaction container by an argon atmosphere.

A fluorine gas is mixed into argon so that a fluorine gas concentration is equal to 0.1%, and introduced into the reaction container for 10 minutes.

After the introduction, supply of the fluorine gas is stopped and the inside of the reaction container is replaced by the argon gas. Then, a sample is taken out. Thus, the sample was prepared.

### Example 2

A sample was prepared in a manner similar to that of the sample 1 except that, in the operation of preparing the sample 1, a temperature of the reaction container was changed to 50° C. and a fluorine concentration was changed to 0.01%.

### Example 3

A sample was prepared in a manner similar to that of the sample 1 except that, in the operation of preparing the sample 1, a temperature of the reaction container was changed to 50° C. and a reaction time was changed to 2 minutes.

### Example 4

A sample was prepared in a manner similar to that of the sample 1 except that, in the operation of preparing the sample 1, before the fluorine gas is introduced, n-eicosane is mixed into the argon gas to be 0.01% and introduced into the reaction container at 25° C. for 30 minutes.

For preparation of n-eicosane, it is heated to 100° C. to be liquefied and a gas generated by its steam pressure is used.

### Example 5

Before a sample prepared under the condition of the sample 1 was taken out from the inside of the reaction container, hydrocarbon was laminated on a surface fluorinated in the manner of the sample 4 under the condition similar to the sample 4. The hydrocarbon layer was fluorinated for 10 minutes with 1% concentration of fluorine gas introduced into the inside of the reaction container and the reaction container kept at a temperature of 25° C.

### Example 6

On a sample prepared under the condition of the sample 5, a hydrocarbon layer was laminated under the condition similar to the sample 4. The hydrocarbon layer was fluorinated under the condition similar to the sample 1 except that a fluorine gas concentration was changed to 0.001%. Further thereon, a hydrocarbon layer was again formed under the condition similar to the sample 4 except that a reaction time was changed to 1 hour. The hydrocarbon layer was fluorinated under the condition similar to the sample 1 except that a fluorine gas concentration was changed to 0.1%.

II. A Method of Evaluating the Prepared Samples

Measurements of a visible light reflectance and a transmittance were carried out by a spectral photometer UV-3150 (Shimadzu Corporation).

With respect to a sample plane, light was projected at an angle of 45°. By using a color-matching function, a transmittance and a reflectance of a Y value among tristimulus values were calculated. The results were organized into the following table 1. For comparison, values of an unprocessed cyclic olefin polymer similar in configuration to the above-mentioned samples are shown.

TABLE 1

| | light transmittance (%) | surface reflectance (%) |
|---|---|---|
| sample 1 | 93.2 | 3.2 |
| sample 2 | 93.3 | 3.1 |
| sample 3 | 93.5 | 2.8 |
| sample 4 | 94.0 | 2.2 |
| sample 5 | 95.1 | 2.0 |
| sample 6 | 97.1 | 1.3 |
| comparative example 1 | 91.8 | 4.0 |

### INDUSTRIAL APPLICABILITY

The plastic member and the transparent member with a fluorinated layer formed on its surface according to the present invention are applicable for quality improvement of various optical members, such as a lens, a prism, and an optical sheet.

The plastic member and the transparent member with a fluorinated layer formed on its surface according to the present invention can widely be used as one component of optical devices in general, a flat-panel display device, such as an organic EL, an LCD, and a PDP, and other electronic devices.

1. A method of manufacturing a transparent member, comprising a step of preparing a member having a transparent hydrocarbon polymer at least on a surface portion thereof and a step of exposing a surface of the transparent hydrocarbon polymer to an atmosphere containing a fluorine gas to thereby fluorinate at least a part of the transparent hydrocarbon polymer.

2. The method of manufacturing a transparent member as claimed in claim 1, wherein the member is substantially transparent plastic.

3. The method of manufacturing a transparent member as claimed in claim 1, wherein the transparent hydrocarbon polymer is a cyclic olefin polymer.

4. The method of manufacturing a transparent member as claimed in claim 1, wherein the atmosphere containing a fluorine gas is a mixed gas atmosphere of the fluorine gas and an inert gas, at least one of a moisture concentration and an oxygen concentration in the inert gas being 1 ppm or less.

5. A transparent member manufactured by the method of manufacturing a transparent member claimed in claim 1.

6. The method of manufacturing a transparent member as claimed in claim 1, wherein the step of preparing includes a step of forming a film of the transparent hydrocarbon polymer on a substantially transparent plastic substrate.

7. The method of manufacturing a transparent member as claimed in claim 6, wherein the plastic substrate contains the transparent hydrocarbon polymer.

8. The method of manufacturing a transparent member as claimed in claim 6, wherein the plastic substrate has a first principal surface having a substantially planar or curved shape and a second principal surface having a substantially planar or curved shape and opposite to the first principal surface, the step of forming the film comprising a step of forming the film on at least one of the first principal surface and the second principal surface

9. A method of manufacturing a transparent member, including a step of forming a hydrocarbon material film on a substantially transparent plastic substrate and a step of bringing a surface of the hydrocarbon material film into contact with an atmosphere containing a fluorine gas to fluorinate at least a part of the hydrocarbon material film.

10. A transparent member manufactured by the method of manufacturing a transparent member claimed in claim 9.

11. The method of manufacturing a transparent member as claimed in claim 9, wherein the step of forming the film includes a step of bringing the surface of the substrate into contact with a liquid or a gaseous organic material to adhere the hydrocarbon material film onto the substrate.

12. The method of manufacturing a transparent member as claimed in claim 9, wherein the plastic substrate has a first principal surface having a substantially planar or curved shape and a second principal surface having a substantially planar or curved shape and opposite to the first principal surface, the forming step having a step of forming the film on at least one of the first principal surface and the second principal surface.

13. The method of manufacturing a transparent member as claimed in claim 9, wherein the plastic substrate contains a transparent hydrocarbon polymer.

14. The method of manufacturing a transparent member as claimed in claim 13, wherein the transparent hydrocarbon polymer is a cyclic olefin polymer.

15. The method of manufacturing a transparent member as claimed in claim 9, further including a step of forming a second hydrocarbon material film on the fluorinated hydrocarbon material film and a step of bringing a surface of the second hydrocarbon material film into contact with an atmosphere containing a fluorine gas to fluorinate at least a part of the second hydrocarbon material film.

16. The method of manufacturing a transparent member as claimed in claim 15, further including a step of forming a second hydrocarbon layer on the fluorinated hydrocarbon layer and a step of exposing a surface of the second hydrocarbon layer to an atmosphere containing a fluorine gas to fluorinate the second hydrocarbon layer.

17. The method of manufacturing a transparent member as claimed in claim 16, wherein the transparent hydrocarbon polymer is a cyclic olefin polymer.

18. The method of manufacturing a transparent member as claimed in claim 9, wherein the transparent plastic substrate comprises a cyclic olefin polymer, the second hydrocarbon material film comprising straight-chain saturated or unsaturated hydrocarbon.

19. The method of manufacturing a transparent member as claimed in claim 16, wherein the transparent hydrocarbon polymer is a cyclic olefin polymer, the second hydrocarbon layer comprising straight-chain saturated or unsaturated hydrocarbon.

20. A method of manufacturing a transparent member, including a step of exposing a surface of at least a part of a transparent hydrocarbon polymer member to vaporized hydrocarbon or liquid hydrocarbon to form a hydrocarbon layer having a composition different from that of the polymer base material and a step of exposing the hydrocarbon layer to an atmosphere containing a fluorine gas to fluorinate the hydrocarbon layer.

21. The method of manufacturing a transparent member as claimed in claim 20, wherein the transparent hydrocarbon polymer is a cyclic olefin polymer.

22. The method of manufacturing a transparent member as claimed in claim 20, wherein the vaporized hydrocarbon is vaporized from a hydrocarbon material which is solid at a temperature when the surface of the transparent hydrocarbon polymer member is exposed.

23. The method of manufacturing a transparent member as claimed in claim 20, wherein the atmosphere containing a fluorine gas is a mixed gas atmosphere of the fluorine gas and an inert gas, at least one of a moisture concentration and an oxygen concentration in the inert gas being 1 ppm or less.

24. A transparent member manufactured by the method of manufacturing a transparent member claimed in claim 20.

25. A transparent member having a transparent hydrocarbon polymer at least on a surface thereof, at least a part of a surface of the transparent hydrocarbon polymer being fluorinated.

26. The transparent member as claimed in claim 25, wherein the transparent hydrocarbon polymer is a cyclic olefin polymer.

27. An electronic device including the transparent member claimed in claim 25 as a component.

28. A plastic member containing at least carbon atoms and hydrogen atoms, wherein at least a part of the hydrogen atoms on and adjacent to a surface of at least a part of the plastic member are substituted by fluorine atoms.

29. The plastic member as claimed in claim 28, wherein a concentration of the fluorine atoms adjacent to the surface is reduced from the surface toward the inside.

30. The plastic member as claimed in claim 29, comprising, on the surface, a fluorocarbon film which comprises carbon atoms and fluorine atoms as main components and which has a fluorine atom concentration substantially constant in a thickness direction.

31. The plastic member as claimed in claim 29, wherein the surface has a lens structure.

32. The plastic member as claimed in claim 29, wherein the surface has a plurality of lens structures arranged in an array.

33. The plastic member as claimed in claim 28, having a first principal surface having a substantially planar or curved shape and a second principal surface having a substantially planar or curved shape and opposite to the first principal surface, wherein at least a part of the hydrogen atoms on or adjacent to a surface of at least a part of at least one of the first principal surface and the second principal surface is substituted by fluorine atoms.

34. The plastic member as claimed in claim 28, having a membrane structure.

35. The plastic member as claimed in claim 28, having a filter structure.

36. The plastic member as claimed in claim 28, comprising a cyclic olefin polymer.

37. The plastic member as claimed in claim 28, having a flat plate shape.

38. The plastic member as claimed in claim 37, wherein both principal surfaces of the plastic member having a flat plate shape are provided with at least one of a convex structure, a concave structure, and a concavo-convex structure.

39. The plastic member as claimed in claim 37, wherein at least one principal surface of the plastic member of a flat plate shape is provided with at least one of a convex structure, a concave structure, and a concavo-convex structure.

40. The plastic member as claimed in claim 39, wherein at least one of the first principal surface and the second principal surface has at least one lens structure.

41. The plastic member as claimed in claim 28, being substantially transparent with respect to light.

42. The plastic member as claimed in claim 41, having a first principal surface having a substantially planar or curved shape and a second principal surface having a substantially planar or curved shape and opposite to the first principal surface, wherein at least one of the first principal surface and the second principal surface has at least one surface structure which scatters, refracts, or reflects light.

43. An electronic device including, as a component, the plastic member claimed in claim 28.
